(19) United States
(12) Patent Application Publication
(10) Pub. No.: US 2026/0082764 A1
(43) Pub. Date: Mar. 19, 2026

(54) OPTOELECTRONIC DEVICE AND PREPARATION METHOD THEREOF, AND DISPLAY DEVICE

(71) Applicants: Guangdong Juhua Research Institute of Advanced Display, Guangzhou (CN); Shenzhen TCL High-Tech Development Co., Ltd., Shenzhen (CN)

(72) Inventor: Fuqiang QIANG, Guangzhou (CN)

(73) Assignees: Guangdong Juhua Research Institute of Advanced Display, Guangzhou (CN); Shenzhen TCL High-Tech Development Co., Ltd., Shenzhen (CN)

(21) Appl. No.: 19/301,854

(22) Filed: Aug. 15, 2025

(30) Foreign Application Priority Data
Sep. 19, 2024 (CN) 202411310748.1

(51) Int. Cl. H10K 50/12; H10K 50/165; H10K 50/17; H10K 59/12; H10K 71/15; H10K 71/60

(52) U.S. Cl. CPC H10K 50/12; H10K 50/165; H10K 50/171; H10K 59/12; H10K 71/15; H10K 71/611

(57) ABSTRACT

The present disclosure provides an optoelectronic device and a preparation method thereof, and a display device. The optoelectronic device includes an anode, a light-emitting layer, an electron functional layer, and a cathode staked in this order. A material of the electron functional layer includes an N-type metal oxide particle and a dopant, and an electronegativity of the dopant ranges from 2.50 to 5.00. The optoelectronic devices described in the present disclosure have a long lifetime.

This application claims priority to Chinese Application No. 202411310748.1, entitled “OPTOELECTRONIC DEVICE AND PREPARATION METHOD THEREOF, AND DISPLAY DEVICE”, filed on Sep. 19, 2024. The entire disclosures of the above application are incorporated herein by reference.

### TECHNICAL FIELD

The present disclosure relates to a field of optoelectronic device technologies, and more particularly, to an optoelectronic device and a preparation method thereof, and a display device.

### BACKGROUND

Nowadays, the widely used optoelectronic devices are organic light-emitting device (OLED) and quantum dot light-emitting device (QLED). OLED has become the mainstream technology in the field of display technology because of its excellent display performance such as self-illumination, simple structure, ultra-thin and light, fast corresponding speed, wide viewing angle, low power consumption, and flexible display. QLED has the advantages of saturated color of emitted light, adjustable wavelength, low lighting voltage, good solution processability, easy fine control of quantum dots, high photoluminescence, and electroluminescence quantum yield, thereby has become a strong competitor of OLED in recent years.

Conventional OLED device structures and QLED device structures generally include an anode, a hole injection layer, a hole transport layer, a light-emitting layer, an electron transport layer, an electron injection layer, and a cathode. Under the action of the electric field, the holes generated by the anode and the electrons generated by the cathode of the optoelectronic device move and inject into the hole transport layer and the electron transport layer respectively, and finally migrate to the light-emitting layer. When the holes and the electrons meet in the light-emitting layer, energy excitons are generated, thus exciting the light-emitting molecules to produce visible light finally.

However, existing optoelectronic devices have a short lifetime and need to be further improved.

### Technical Solution

In view of this, the present disclosure provides an optoelectronic device and a preparation method thereof, and a display device.

First aspect, the present disclosure provides an optoelectronic device including an anode, a light-emitting layer, an electron functional layer, and a cathode staked in this order. A material of the electron functional layer includes an N-type metal oxide particle and a dopant, and an electronegativity of the dopant ranges from 2.50 to 5.00.

Second aspect, the present disclosure further provides a method of preparing an optoelectronic device, and the method includes:
providing an optoelectronic device preform including a first electrode;
providing an electronic functional material dispersion including an N-type metal oxide particle, a dopant and a first organic solvent, and disposing the electronic functional material dispersion on the optoelectronic device preform to obtain an electron functional layer and an electronegativity of the dopant ranges from 2.50 to 5.00; and
forming a second electrode on the electron functional layer to obtain the optoelectronic device;
where the first electrode is an anode, the second electrode is a cathode, and the optoelectronic device preform further comprises a light-emitting layer disposed on the first electrode; or the first electrode is a cathode electrode, the second electrode is an anode electrode, and the step of forming a second electrode on the electron functional layer comprises: forming a light-emitting layer and a second electrode stacked in this order on the electron functional layer.

Third aspect, the present disclosure further provides a display device including the optoelectronic device described above.

The electron functional layer of the optoelectronic device described in the present disclosure includes the N-type metal oxide particle and the dopant, and the existence of the dopant can improve the lifetime of the optoelectronic device.

### BRIEF DESCRIPTION OF DRAWINGS

In order to more clearly explain the technical solutions in the embodiments of the present disclosure, the figures to be used in the description of the embodiments are briefly described below. It is apparent that the figures in the following description are merely some embodiments of the present disclosure. For those skilled in the art, without involving any creative effort, other figures may be obtained based on these figures.

FIG. 1 is a structure schematic diagram of an optoelectronic device according to an embodiment of the present disclosure;

FIG. 2 is a structure schematic diagram of another optoelectronic device according to an embodiment of the present disclosure;

FIG. 3 is a structure schematic diagram of another optoelectronic device according to an embodiment of the present disclosure;

FIG. 4 is a flowchart of a method of preparing an optoelectronic device according to an embodiment of the present disclosure.

### DETAILED DESCRIPTION

Technical solutions in embodiments of the present disclosure will be clearly and completely described below with reference to the drawings in the embodiments of the present disclosure. It is apparent that, the described embodiments are only a part of embodiments of the present disclosure, rather than all the embodiments. Based on the embodiments in the present disclosure, all other embodiments obtained by those skilled in the art without creative effort fall within the protection scope of the present disclosure. Furthermore, it should be understood that the detailed description described herein is for illustration and explanation of the present disclosure only, and is not intended to limit the present disclosure.

In the present disclosure, unless stated to the contrary, the location words used such as “upper” and “lower” usually refer to the upper and lower in the actual use or working state of the device, specifically the drawing direction in the accompanying figures; while “inner” and “outer” are for the outline of the device. In addition, in the description of the present disclosure, the term “comprising/including “means” comprising/including but not limited to”. The terms first, second, third, etc. are used for indication only, and do not impose numerical requirements or establish order.

In the present disclosure, the term “and/or” is used to describe the association of associated objects, and means that there may be three relationships, for example, “A and/or B” may refer to three cases: the first case refers to the presence of A alone; the second case refers to the presence of both A and B; the third case refers to the presence of B alone, where A and B may be singular or plural.

In the present disclosure, the term “at least one” refers to one or more, and “a plurality of/multiple” refers to two or more. The terms “at least one”, “at least one of the followings”, and the like, refer to any combination of the items listed, including any combination of the singular or the plural items. For example, “at least one of a, b, or c” or “at least one of a, b, and c” may refer to: a, b, c, a-b (i.e., a and b), a-c, b-c, or a-b-c, where a, b, and c may be single or plural (multiple).

In the present disclosure, another layer is formed “on” a certain layer, and the so-called “on” is a broad concept, which may mean that the other layer is formed adjacent to the certain layer, or may mean that another spacer structure layer exists between the other layer and the certain layer. For example, a second electrode is formed “on” the first carrier functional layer, and the so-called “on” may mean that the second electrode is formed adjacent to the first carrier functional layer, or may mean that another spacer structure layer exists between the second electrode and the first carrier functional layer, for example, a light-emitting layer.

Various embodiments of the present disclosure may be presented in a form of range. It should be understood that the description in the form of range is merely for convenience and brevity, and should not be construed as a hard limitation on the scope of the disclosure. Therefore, it should be considered that the recited range description has specifically disclosed all possible subranges, as well as a single numerical value within that range. For example, it should be considered that a description of a range from 1 to 6, more specifically, a range such as from 1 to 3, from 1 to 4, from 1 to 5, from 2 to 4, from 2 to 6, from 3 to 6, etc., and a single number within the range, such as 1, 2, 3, 4, 5, and 6, regardless of the range.

Study results show that the electron transport layer (ETL) of the optoelectronic device can significantly affect its electroluminescence (EL) lifetime. Commonly used materials for electron transport layer of the optoelectronic device include metal oxide particles such as ZnO particles and the like. There is an electrical aging phenomenon during the use of optoelectronic devices, which leads to an increase in the concentration of metal oxides with higher oxidation states, and there is a correlation between the magnitude of electroluminescence loss and the concentration of metal oxides with higher oxidation states.

During the aging process of optoelectronic device, interfacial charge transfer occurs at the interface between the metal oxide particles in the electron transport layer and the luminescent material, which leads to the formation of positively charged defects (such as oxygen vacancies) in the metal oxide particles, and in turn leads to the brightness quenching of the optoelectronic device. While the fast initial EL loss is related to the increase in the defect density in the metal oxide particles in the electron transport layer and the increase in the number of holes leaking to the electron transport layer. Therefore, reducing the generation of metal oxides with higher oxidation states during electrical aging of the optoelectronic device and reducing the number of holes leaking into the electron transport layer are key to improving the performance of the optoelectronic device and realizing the commercialization of the optoelectronic device.

The technical solution of the present disclosure is as follows:

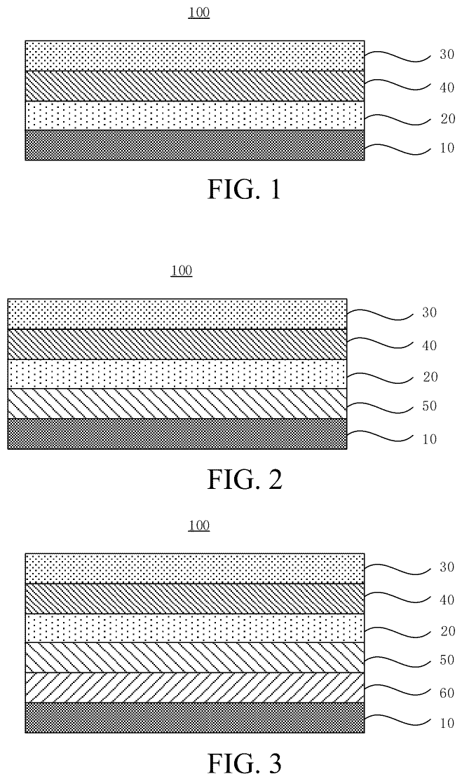

First aspect, referring to FIG. 1, embodiments of the present disclosure provide an optoelectronic device 100 including an anode 10, a light-emitting layer 20, and a cathode 30 staked in this order. The optoelectronic device 100 further includes an electron functional layer 40 disposed between the cathode 30 and the light-emitting layer 20. A material of the electron functional layer 40 includes an N-type metal oxide particle and a dopant. An electronegativity of the dopant ranges from 2.50 to 5.00.

The dopant and the N-type metal oxide particle is connected by intermolecular force.

The electron functional layer 40 of the optoelectronic device 100 described in the present disclosure includes the N-type metal oxide particle and the dopant, and the dopant has high electronegativity and a binding effect on electrons. Doping the dopant in the electron functional layer 40 can slow down the charge transfer from the electron functional layer 40 to the light-emitting layer 20, thereby slowing down the charge transfer at the interface between the electron functional layer 40 and the light-emitting layer 20, reducing or even avoiding the formation of positively charged defects in the N-type metal oxide particle at the interface, avoiding the brightness quenching of the optoelectronic device 100, reducing the initial EL loss rate of the optoelectronic device 100, thereby further improving the electroluminescence stability of the optoelectronic device 100, and improving the lifetime of the optoelectronic device 100.

In addition, the dopant incorporated in the electron functional layer 40 has high electronegativity itself, and can interacts with the N-type metal oxide particle, thereby affects the electronic structure of the N-type metal oxide particle, and causes itself to generate low energy states. The low energy states can provide suitable energy state positions for holes (positive charges), thereby acting as a hole scavenger, effectively neutralizing positive charge defects (holes) leaked to the electron functional layer 40 as a hole trapping agent, thereby reducing the initial EL loss rate of the optoelectronic device 100, improving the electroluminescence stability of the optoelectronic device 100, and improving the lifetime of the optoelectronic device 100.

Furthermore, the dopant neutralizes the holes leaked into the electron functional layer 40 to prevent the holes from residing at the metal cation sites that can form high-valence metal cations, thereby reducing the formation of high-oxidation state metal cations, reducing the formation of high-oxidation state metal oxides, and reducing or even avoiding an increase in the concentration of high-oxidation state N-type metal oxides, thereby reducing the initial EL loss rate of the optoelectronic device 100, improving the electroluminescence stability of the optoelectronic device 100, and improving the lifetime of the optoelectronic device 100.

The metal cation refers to a metal cation in the N-type metal oxide particle.

It should be noted that the metal cation refers to a metal cation of the N-type metal oxide particle.

In some embodiments, the electronegativity of the dopant ranges from 2.66 to 4.50. Furthermore, in some embodiments, the electronegativity of the dopant ranges from 2.66 to 3.98. Furthermore, in some embodiments, the electronegativity of the dopant ranges from 2.66 to 3.80. Furthermore, in some embodiments, the electronegativity of the dopant ranges from 2.66 to 3.50. Furthermore, in some embodiments, the electronegativity of the dopant ranges from 2.66 to 3.30. Furthermore, in some embodiments, the electronegativity of the dopant ranges from 2.66 to 3.20. Furthermore, in some embodiments, the electronegativity of the dopant ranges from 2.66 to 3.00.

For example, the electronegativity of the dopant may be 2.50, 2.66, 2.70, 2.80, 2.90, 3.00, 3.10, 3.20, 3.30, 3.40, 3.50, 3.60, 3.70, 3.80, 3.90, 4.0, 4.10, 4.20, 4.30, 4.40, 4.50, 4.60, 4.70, 4.80, 4.90, 5.00, and a range between any two values, etc.

It can be understood that the electron functional layer 40 may include one or more of an electron transport layer and an electron injection layer. It can be understood that when the electron functional layer 40 includes the electron transport layer and the electron injection layer, the electron injection layer is disposed between the electron transport layer and the cathode.

In some embodiments, the dopant may include a halogen. Furthermore, the halogen may include a halogen elemental substance, and the halogen elemental substance may include, but not limited to, one or more of Br₂ and I₂.

In some embodiments, the N-type metal oxide particle may include, but not limited to, one or more of a first doped metal oxide particle and a first undoped metal oxide particle. A material of the first undoped metal oxide particle includes one or more of ZnO, TiO₂, and SnO₂. A metal oxide of the first doped metal oxide particle includes one or more of ZnO, TiO₂, and SnO₂, and a doping element of the first doped metal oxide particle includes one or more of Al, Mg, Li, Mn, Y, La, Cu, Ni, Zr, Ce, In, and Ga.

In some embodiments, a molar percentage content of the doping element of the first doped metal oxide particle ranges from 0.01% to 15%, for example, 1%, 2%, 3%, 4%, 5%, 6%, 7%, 8%, 9%, 10%, 11%, 12%, 13%, 14%, 15%, and a range between any two values, etc.

In some embodiments, in the electron functional layer 40, a mass ratio of the N-type metal oxide particle to the dopant is (60-300):1, for example, 60:1, 80:1, 100:1, 120:1, 150:1, 180:1, 200:1, 120:1, 230:1, 250:1, 260:1, 280:1, 300:1, and a range between any two ratios, etc. Within the range of the mass ratio, the charge transfer at the interface between the electron functional layer 40 and the light-emitting layer 20 can be effectively slowed down, thereby reducing or even avoiding the formation of positively charged defects in the N-type metal oxide particle at the interface, effectively neutralizing positive charge defects (holes) leaked into the electron functional layer 40, effectively reducing the formation of high oxidation state metal cations, thereby avoiding brightness quenching of the optoelectronic device 100, reducing the initial EL loss rate of the optoelectronic device 100, improving the electroluminescence stability of the optoelectronic device 100, and improving the lifetime of the optoelectronic device 100.

In some embodiments, an average particle diameter of the N-type metal oxide particle ranges from 3 nm to 10 nm, for example, 3 nm, 4 nm, 5 nm, 6 nm, 7 nm, 8 nm, 9 nm, 10 nm, and a range between any two values, etc. Within the particle size range, the electron functional layer 40 can have better film formation uniformity, and the energy level matching degree between the material of the electron functional layer 40 and the material of the light-emitting layer 20 can be more suitable, which is beneficial for the optoelectronic device 100 to have higher electroluminescence stability and longer lifetime.

It should be noted that the average particle diameter of the N-type metal oxide particle in the present disclosure is measured by a transmission electron microscope TEM.

Referring to FIG. 2, in some embodiments, the optoelectronic device 100 further includes a hole transport layer 50 disposed between the anode 10 and the light-emitting layer 20.

Referring to FIG. 3, in some embodiments, the optoelectronic device 100 further includes a hole injection layer 60 disposed between the anode 10 and the hole transport layer 50.

The anode 10 and the cathode 30 are electrodes known in the art for use in optoelectronic devices, and may independently include, for example, but are not limited to, a doped metal oxide electrode, a composite electrode, a graphene electrode, a carbon nanotube electrode, a metal elemental electrode, or an alloy electrode. A material of the doped metal oxide electrode may include, but not limited to, one or more of indium-doped tin oxide (ITO), fluorine-doped tin oxide (FTO), antimony-doped tin oxide (ATO), aluminum-doped zinc oxide (AZO), gallium-doped zinc oxide (GZO), indium-doped zinc oxide (IZO), magnesium-doped zinc oxide (MZO), aluminum-doped magnesium oxide (AMO), and cadmium-doped zinc oxide. The composite electrode is an electrode formed by laminating two or more conductive materials, for example, AZO/Ag/AZO, AZO/Al/AZO, ITO/Ag/ITO, ITO/Al/ITO, ZnO/Ag/ZnO, ZnO/Al/ZnO, TiO₂/Ag/TiO₂, TiO₂/Al/TiO₂, ZnS/Ag/ZnS, ZnS/Al/ZnS, Ca/Al, LiF/Ca, LiF/Al, BaF₂/Al, CsF/Al, CaCO₃/Al, BaF₂/Al, and the like. Moreover, “/” represents a laminated structure, and for example, AZO/Ag/AZO represents a composite electrode including an AZO layer, an Ag layer, and an AZO layer stacked in this order. A material of the metal elemental electrode may include, but not limited to, one or more of Ag, Ni, Pt, Au, Ir, Cu, Mo, Al, Ca, Mg, and Ba. The alloy electrodes include, but not limited to, Au:Mg alloy electrode and Ag:Mg alloy electrode.

In some embodiments, the anode is an electrode having a relatively high work function, and may include, for example, but not limited to, a doped metal oxide electrode having a relatively high work function, a metal elemental electrode having a relatively high work function, and a carbon nanotube electrode. The higher work function metal elemental electrode may be selected from, but not limited to, Ni, Pt, Au, Ag, Ir, and the like.

In some embodiments, the cathode is an electrode having a relatively low work function, and may include, for example, but not limited to, a metal elemental electrode having a relatively low work function, a composite electrode having a relatively low work function, and an alloy electrode having a relatively low work function. The metal elemental electrode having a relatively low work function may be Ca, Ba, Al, Mg, and the like. The composite electrode having a relatively low work function may be Ca/Al, LiF/Ca, LiF/Al, BaF₂/Al, CsF/Al, CaCO₃/Al, BaF₂/Ca/Al, and the like. The alloy electrode may be Au:Mg and Ag:Mg, and the like.

A material of the light-emitting layer 20 may include, but not limited to, one or more of an organic light-emitting material and a quantum dot light-emitting material.

The organic light-emitting material may include, but not limited to, CBP:Ir(mppy)₃ (4,4′-bis(N-carbazole)-1,1′-biphenyl:tris [2-(p-tolyl) pyridinyl iridium (III)), TCTX:Ir(mmpy) (4,4′,4″-tris(carbazol-9-yl) triphenylamine:tris [2-(p-tolyl) pyridinyl iridium), a diarylanthracene derivative, a stilbene aromatic derivative, a pyrene derivative, a fluorene derivative, a TBPe fluorescent material, a TTPX fluorescent material, a TBRb fluorescent material, a DBP fluorescent material, a delayed fluorescent material, a TTA material, a TADF (thermally activated delay) material, a B—N covalent bonding-containing polymer, a HLCT (hybrid local charge transfer excited state) material, an exciplex (exciplex) luminescent material, polyacetylene and its derivatives, polyphenylene and its derivatives, polythiophene and its derivatives, and polyfluorene and its derivatives.

The quantum dot light-emitting material may include, but not limited to, one or more of a single structure quantum dot, a core-shell structure quantum dot, and a perovskite-type semiconductor material. The core-shell structured quantum dot includes one or more shell layers.

A material of the single structure quantum dot, a material of the core of the core-shell structure quantum dot, and a material of the shell of the core-shell structure quantum dot may include, but not limited to, one or more of a Group II-VI compound, a Group IV-VI compound, a Group III-V compound, and a Group I-III-VI compound, respectively. The Group II-VI compound may include, but not limited to, one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, and HgZnSTe. The Group IV-VI compound may include, but not limited to, one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, and SnPbSTe. The Group III-V compound may include, but not limited to one or more of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, InNSb, AIPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and InAlPSb. The Group I-III-VI compound may include, but not limited to, one or more of CuInS₂, CuInSe₂, and AgInS₂.

For example, the core-shell structured quantum dot may include, but not limited to, one or more of CdSe/CdSeS/CdS, InP/ZnSeS/ZnS, CdZnSe/ZnSe/ZnS, CdSeS/ZnSeS/ZnS, CdSe/ZnS, CdSe/ZnSe/ZnS, ZnSe/ZnS, ZnSeTe/ZnS, CdSe/CdZnSeS/ZnS, and InP/ZnSe/ZnS.

The perovskite-type semiconductor material may include, but not limited to, a doped or undoped inorganic perovskite-type semiconductor, or an organic-inorganic hybrid perovskite-type semiconductor. A general structural formula of the inorganic perovskite-type semiconductor is AMX₃, where A is a Cs⁺ ion, M is a divalent metal cation including one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺, and Eu²⁺, and X is a halogen anion including one or more of Cl⁻, Br⁻, and I⁻. A general structural formula of the organic-inorganic hybrid perovskite-type semiconductor is BMX₃, where B is an organic amine cation including CH₃(CH₂)ₙ₋₂NH₃⁺ or [NH₃(CH₂)ₙNH₃]²⁺, where n≥2, M is a divalent metal cation including one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺, and Eu²⁺, and X is a halogen anion including one or more of Cl⁻, Br⁻, and I⁻.

A material of the hole transport layer 50 may be the material known in the art for hole transport layers, and may include, for example, but not limited to, one or more of an organic hole transport material and an inorganic hole transport material.

The organic hole transport material may be selected from, but not limited to, one or more of 4,4′-N,N′-dicarbazolyl-biphenyl (CBP), poly [bis(4-phenyl) (2,4,6-trimethylphenyl) amine](PTAA), N, N′-diphenyl-N, N′-bis (1-naphthyl)-1,1′-biphenyl-4,4′-diamine (α-NPD), N,N′-diphenyl-N,N′-bis (3-methylphenyl)-(1,1′-biphenyl)-4,4′-diamine (TPD), poly (N,N′-bis (4-butylphenyl)-N,N′-bis (phenyl) benzidine) (Poly-TPD), N,N′-bis(3-methylphenyl)-N,N′-bis (phenyl)-spiro (spiro-TPD), N,N′-bis (4-(N, N′-diphenyl-amino) phenyl)-N,N′-diphenylbenzidine (DNTPD), 4,4′,4′-tris (N-carbazolyl)-triphenylamine (TCTA), 4,4′,4′-tris (N-3-methylphenyl-N-phenylamino) triphenylamine (m-MTDATA), poly [(9,9′-dioctylfluorene-2,7-diyl)-co-(4,4′-dioctylfluorene-2,7-diyl)-co-(4,4′-(N-(4-sec-butylphenyl)-co-(4,4′-(N-(4-sec-butylphenyl) diphenylamine)](TFB), Poly (N-vinylcarbazole) (PVK) and its derivatives, N,N′-bis(1-naphthyl)-N,N′-diphenyl-1,1′-biphenyl-4-4′-diamine (NPB), spiro NPB, poly (phenylenevinylene) (PPV), poly [2-methoxy-5-(2-ethylhexyloxy)-1, 4-phenylenevinylene](MEH-PPV), poly [2-methoxy-5-(3′,7′-dimethyloctoxy)-1,4-phenylenevinylene](MOMO-PPV), 2,2′,7,7′-tetrakis [N,N-bis(4-methoxyphenyl) amino]-9,9′-spirobifluorene (spiro-omeTAD), 4,4′-cyclohexylbis [N,N-bis (4-methylphenyl) aniline](TAPC), 1,3-bis(carbazol-9-yl) benzene (MCP), polyaniline, polypyrrole, poly (p) phenylene vinylidene, aromatic tertiary amines, polynuclear aromatic tertiary amines, 4,4′-bis (p-carbazolyl)-1,1′-biphenyl compounds, N,N,N′,N′-tetraarylbenzidine, PEDOT: PSS and its derivatives, polymethacrylates and its derivatives, poly (9, 9-octylfluorene) and its derivatives, and poly (spirofluorene) and its derivatives.

The inorganic hole transport material may be selected from, but not limited to, one or more of a doped graphene, an undoped graphene, a P-type metal oxide particle, a metal sulfide, a metal selenide, and a metal nitride. The P-type metal oxide particle may include, but not limited to, one or more of a second doped metal oxide particle and a second undoped metal oxide particle. The metal oxide of the second doped metal oxide particle and the metal oxide of the second undoped metal oxide particle may each independently include, but not limited to, one or more of MoO₃, WO₃, NiO, CrO₃, CuO, Cu₂O, and V₂O₅, and a doping element in the second doped metal oxide particle may include, but not limited to, one or more of Mo, W, Ni, Cr, Cu, and V. The metal sulphide may include, but not limited to, one or more of CuS, MoS₃, and WS₃. The metal selenide may include, but not limited to, one or more of MoSe₃, and WSe₃. The metal nitride may include, but not limited to, P-type gallium nitride.

A material of the hole injection layer 60 may be the material known in the art for hole injection layers, for example, may be selected from, but not limited to, one or more of, 2,3,6,7,10,11-hexacyano-1,4,5,8,9,12-hexaazabenzophenanthrene (HAT-CN), PEDOT, PEDOT:PSS, PEDOT:PSS:s-MoO₃ derivative (PEDOT:PSS:s-MoO₃), 4,4′,4′-tris (N-3-methylphenyl-N-phenylamino) triphenylamine (m-MTDATA), tetracyanoquinone dimethane (F4-TCQN), copper phthalocyanine, nickel oxide, molybdenum oxide, tungsten oxide, vanadium oxide, molybdenum sulfide, tungsten sulfide, and copper oxide.

In some embodiments, a thickness of the anode 10 ranges from 0.1 mm to 1 mm.

In some embodiments, a thickness of the light-emitting layer 20 ranges from 20 mm to 60 nm.

In some embodiments, a thickness of the electron functional layer 40 ranges from 10 mm to 30 nm.

In some embodiments, a thickness of the cathode 30 ranges from 60 mm to 100 nm.

In some embodiments, a thickness of the hole transport layer 50 ranges from is 20 mm to 40 nm.

In some embodiments, a thickness of the hole injection layer 60 ranges from 10 mm to 100 nm.

It can be understood that the optoelectronic device 100 may also add some functional layers conventionally used for optoelectronic devices to help improve the performance of the optoelectronic device, such as an electron blocking layer, a hole blocking layer, an electron injection layer, and the like.

It can be understood that the materials of each layer of the optoelectronic device 100 can be adjusted according to the light emission requirements of the optoelectronic device 100.

In some embodiments, the optoelectronic device 100 further includes a substrate disposed on a side of the anode 10 away from the light-emitting layer 20, or the substrate is disposed on a side of the cathode 30 away from the light-emitting layer 20.

The substrate may be a rigid substrate or a flexible substrate. In some embodiments, a material of the substrate may include, but not limited to, one or more of glass, silicon wafer, polycarbonate, polymethyl methacrylate, polyethylene terephthalate, polyethylene naphthalate, polyamide, and polyethersulfone.

It can be understood that the optoelectronic device 100 may be an upright optoelectronic device or an inverted optoelectronic device.

It can be understood that the optoelectronic device 100 may be a quantum dot optoelectronic device (QLED) or an organic optoelectronic device (OLED)

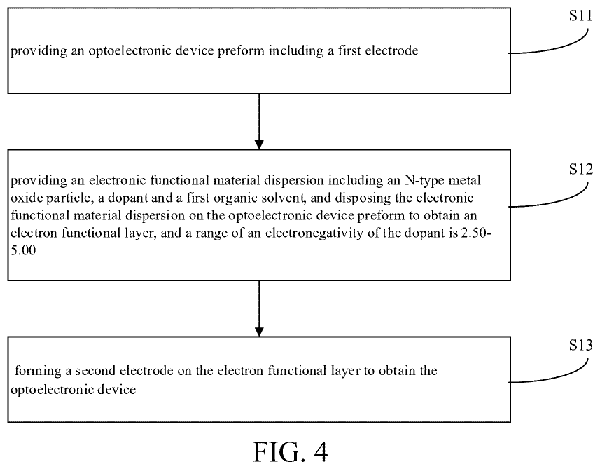

Second aspect, referring to FIG. 1 and FIG. 4, embodiments of the present disclosure further provide a method of preparing an optoelectronic device, and the method includes:
Step S11: providing an optoelectronic device preform including a first electrode;
Step S12: providing an electronic functional material dispersion including an N-type metal oxide particle, a dopant and a first organic solvent, and disposing the electronic functional material dispersion on the optoelectronic device preform to obtain an electron functional layer 40, and a range of an electronegativity of the dopant is 2.50-5.00;
In step S13: forming a second electrode on the electron functional layer 40 to obtain the optoelectronic device 100.

Moreover, the first electrode is an anode 10, the second electrode is a cathode 30, and the optoelectronic device preform further includes a light-emitting layer 20 disposed on the first electrode. Alternatively, the first electrode is a cathode electrode 30, the second electrode is an anode electrode 10, and the step of forming a second electrode on the electron functional layer 40 includes: forming a light-emitting layer 20 and a second electrode stacked in this order on the electron functional layer 40.

Referring to FIG. 2, when the first electrode is the anode 10 and the second electrode is the cathode 30, in some embodiments, the optoelectronic device preform further includes a hole transport layer 50 disposed between the first electrode and the light-emitting layer 20.

Referring to FIG. 3, when the first electrode is the anode 10 and the second electrode is the cathode 30, in some embodiments, the optoelectronic device preform further includes a hole transport layer 50 and a hole injection layer 60 disposed between the first electrode and the hole transport layer 50.

Referring to FIG. 2, when the first electrode is the cathode 30 and the second electrode is the anode 10, in some embodiments, the step S13 includes: sequentially forming a light-emitting layer 20, a hole transport layer 50, and a second electrode on the electron functional layer 40.

Referring to FIG. 3, when the first electrode is the cathode 30 and the second electrode is the anode 10, in some embodiments, the step S13 includes: sequentially forming a light-emitting layer 20, a hole transport layer 50, a hole injection layer 60, and a second electrode on the electron functional layer 40.

The method of forming the second electrode, the method of disposing the electron functional material dispersion on the optoelectronic device preform, the method of forming the hole transport layer 50, and the method of forming the hole injection layer 60 can be independently implemented by conventional techniques in the art, such as chemical method or physical method. The chemical method includes a chemical vapor deposition method, a continuous ion layer adsorption and reaction method, an anodic oxidation method, electrolytic deposition method, and a co-precipitation method. The physical method includes a physical coating method and a solution method. The physical coating method includes a thermal evaporation coating method, an electron beam evaporation coating method, a magnetron sputtering method, a multi-arc ion coating method, a physical vapor deposition method, an atomic layer deposition method, a pulsed laser deposition method, and the like. The solution method may be a spin coating method, a printing method, an ink jet printing method, a blade coating method, a printing method, a dipping and pulling method, an immersion method, a spray coating method, a roll coating method, a casting method, a slit coating method, a strip coating method, and the like.

In some embodiments, the method of disposing the electron functional material dispersion on the optoelectronic device preform is the solution method.

In some embodiments, after disposing the electron functional material dispersion on the optoelectronic device preform further includes annealing.

In some embodiments, a temperature of the annealing ranges from 100° C. to 200° C., for example, 100° C., 120° C., 130° C., 150° C., 160° C., 170° C., 180° C., 200° C., and a range between any two values, etc. A time of the annealing ranges from 10 minutes to 60 minutes, for example, 10 minutes, 20 minutes, 30 minutes, 40 minutes, 50 minutes, 60 minutes, and a range between any two values, etc. Within the temperature range and the time range, it is beneficial to prepare an optoelectronic device with better luminescence uniformity and longer lifetime.

The N-type metal oxide particle and the dopant are described above and will not be described herein.

It should be noted that when the dopant is the halogen elemental substance, after the halogen elemental substance is added to the electron functional layer material, the halogen atom may interact with the metal oxide molecule in the N-type metal oxide particle to generate intermolecular force, so that the halogen elemental substance is no longer in a free state, and therefore, the halogen elemental substance may not be removed by a process such as drying and annealing used in the preparation of the optoelectronic device.

The first organic solvent may include, but limited to, one or more of an alcohol solvent and an alcohol ether solvent. The alcoholic solvent may include, but not limited to, one or more of ethanol, isopropyl alcohol, butanol, n-pentanol, and isoamyl alcohol. The alcohol ether solvent may include, but not limited to, ethylene glycol monomethyl ether.

In some embodiments, a concentration of the N-type metal oxide particle in the electron functional material dispersion ranges from 10 mg/mL to 30 mg/mL, for example, 10 mg/mL, 15 mg/mL, 20 mg/mL, 25 mg/mL, 30 mg/mL, and a range between any two values, etc. Within the concentration range, it is advantageous to make the prepared electron functional layer 40 more uniform and have more suitable conductivity.

In some embodiments, a concentration of the dopant in the electron functional material dispersion ranges from 0.1 mg/mL to 0.5 mg/mL, for example, 0.1 mg/mL, 0.2 mg/mL, 0.3 mg/mL, 0.4 mg/mL, 0.5 mg/mL, and a range between any two values, etc. Within the concentration range, the dopant has good dispersibility, which is advantageous for the prepared electron functional layer 40 to have an appropriate amount of dopant, and further advantageous for the prepared optoelectronic device to have stable electroluminescence and longer lifetime.

In some embodiments, a method of preparing the electronic functional material dispersion includes the following steps:
Step S121: dissolving a metal cation source in a second organic solvent to obtain a metal cation source solution;
Step S122: adding an alkali to the metal cation source solution to cause a metal cation of the metal cation source to react to generate a metal oxide and obtain a metal oxide solution;
Step S123: adding a precipitant to the metal oxide solution to obtain an N-type metal oxide particle;
Step S124: dispersing the N-type metal oxide particle in the first organic solvent to obtain an N-type metal oxide particle dispersion;
Step S125: adding a dopant to the N-type metal oxide particle dispersion to obtain the electronic functional material dispersion.

In step S121:

In some embodiments, the metal cation source may include, but not limited to, one or more of a zinc source, a titanium source, and a tin source.

In some embodiments, the zinc source may include, but not limited to, one or more of zinc acetate, zinc sulfate, zinc nitrate, and zinc chloride.

In some embodiments, the titanium source may include, but not limited to, one or more of titanium acetate, titanium sulfate, titanium nitrate, and titanium chloride.

In some embodiments, the tin source may include, but not limited to, one or more of tin acetate, tin sulfate, tin nitrate, and tin chloride.

In some embodiments, the second organic solvent is an organic solvent known for the preparation of metal oxide particle, and may include, for example, but not limited to, one or more of dimethyl sulfoxide (DMSO), and dimethylformamide (DMF).

In some embodiments, a concentration of the metal cation source in the metal cation source solution ranges from 0.1 mol/L to 1 mol/L, for example, 0.1 mol/L, 0.2 mol/L, 0.3 mol/L, 0.4 mol/L, 0.5 mol/L, 0.6 mol/L, 0.7 mol/L, 0.8 mol/L, 0.9 mol/L, 1 mol/L, and a range between any two numerical values, etc. Within the concentration range, it is advantageous to prepare uniform and stable N-type metal oxide particle.

In step S122:

In some embodiments, the alkali may include, but not limited to, one or more of potassium hydroxide, sodium hydroxide, aqueous ammonia, and tetramethylammonium hydroxide.

A molar ratio of the hydroxide radical in the alkali to the metal cation in the metal cation source is (1.5-3.0):1, for example, 1.5:1, 1.8:1, 2:1, 2.2:1, 2.3:1, 2.5:1, 2.6:1, 2.7:1, 2.8:1, 2.9:1, 3:1, and a range between any two ratios, etc. Within the above ratio range, it is advantageous to sufficiently and efficiently convert the metal cation source into the metal hydroxide, and it is advantageous to prepare uniformly stable N-type metal oxide particles.

In some embodiments, adding an alkali to the metal cation source solution includes dissolving the alkali in a third organic solvent to obtain an alkali solution, and adding the alkali solution to the metal cation source solution.

The third organic solvent may include, but not limited to, one or more of an alcohol solvent and an alcohol ether solvent. The alcoholic solvent may include, but not limited to, one or more of ethanol, isopropyl alcohol, butanol, n-pentanol, and isoamyl alcohol. The alcohol ether solvent includes, but not limited to, ethylene glycol monomethyl ether.

In some embodiments, a concentration of the alkali in the alkali solution ranges from 0.1 mol/L to 1 mol/L, for example, 0.1 mol/L, 0.2 mol/L, 0.3 mol/L, 0.4 mol/L, 0.5 mol/L, 0.6 mol/L, 0.7 mol/L, 0.8 mol/L, 0.9 mol/L, 1 mol/L, and a range between any two numerical values, etc. Within the concentration range, it is advantageous to prepare uniform and stable N-type metal oxide particles.

In some embodiments, a pH of the alkali solution ranges from 12 to 14, for example, 12, 12.5, 13, 13.5, 14, and a range between any two values, etc. Within the pH range, it is advantageous to prepare uniform and stable N-type metal oxide particles.

In some embodiments, after adding an alkali to the metal cation source solution further includes: stirring for 1-4 h. Thereby, it is advantageous for the metal cation source to be sufficiently reacted with the alkali.

It can be understood that the material of the N-type metal oxide particle may include one or more of zinc oxide, titanium oxide, and tin oxide.

In step S123:

The precipitant is a weakly polar organic compound, and the weakly polar organic compound may include, but not limited to, one or more of ethyl acetate, n-hexane, and n-heptane.

A volume ratio of the precipitant to the metal oxide solution is (3-6):1, for example, 3:1, 3.5:1, 4:1, 4.5:1, 5:1, 5.5:1, 6:1, and a range between any two ratios, etc.

In step S124:

The first organic solvent is described above, and will not be described herein.

In step S125:

The dopant refers to the above description, and will not be described herein.

The concentration of the N-type metal oxide particle in the electron functional material dispersion and the concentration of the dopant in the electron functional material dispersion are described above, and will not be described herein.

In some embodiments, after adding a dopant to the N-type metal oxide particle dispersion further includes: stirring for 0.5 h-1.5 h. Thereby, it facilitates the homogeneous dispersion of the N-type metal oxide particle and the dopant in the first organic solvent.

In some embodiments, a doping element source is further added to the metal cation source solution, so that the prepared N-type metal oxide particle can be doped with a doping element, which is beneficial to improving the stability of the N-type metal oxide particle.

The doping element source may include, but not limited to, one or more of a magnesium salt, a lithium salt, a manganese salt, an yttrium salt, a lanthanum salt, a copper salt, a nickel salt, a zirconium salt, a cerium salt, an indium salt, a gallium salt, and a tin salt. It will be appreciated that the doping element supplied by the doping element source is different from the type of metal element in the metal cation source.

The magnesium salt may include, but not limited to, one or more of magnesium acetate, magnesium nitrate, magnesium chloride, magnesium bromide, magnesium sulfate, and magnesium acetylacetonate.

The lithium salt may include, but not limited to, one or more of lithium acetate, lithium nitrate, lithium chloride, lithium bromide, lithium sulfate, and lithium acetylacetonate.

The manganese salt may include, but not limited to, one or more of manganese acetate, manganese nitrate, manganese chloride, manganese bromide, manganese sulfate, and manganese acetylacetonate.

The yttrium salt may include, but not limited to, one or more of yttrium acetate, yttrium nitrate, yttrium chloride, yttrium bromide, yttrium sulfate, and yttrium acetylacetonate.

The lanthanum salt may include, but not limited to, one or more of lanthanum acetate, lanthanum nitrate, lanthanum chloride, lanthanum bromide, lanthanum sulfate, lanthanum acetylacetonate.

The copper salt may include, but not limited to, one or more of copper acetate, copper nitrate, copper chloride, copper bromide, copper sulfate, and copper acetylacetonate.

The nickel salt may include, but not limited to, one or more of nickel acetate, nickel nitrate, nickel chloride, nickel bromide, nickel sulfate, and nickel acetylacetonate.

The zirconium salt may include, but not limited to, one or more of zirconium acetate, zirconium nitrate, zirconium chloride, zirconium bromide, zirconium sulfate, zirconium acetylacetonate.

The cerium salt may include, but not limited to, one or more of cerium acetate, cerium nitrate, cerium chloride, cerium bromide, cerium sulfate, and cerium acetylacetonate.

The indium salt may include, but not limited to, one or more of indium acetate, indium nitrate, indium chloride, indium bromide, indium sulfate, and indium acetylacetonate.

The gallium salt may include, but not limited to, one or more of gallium acetate, gallium nitrate, gallium chloride, gallium bromide, gallium sulfate, gallium acetylacetonate.

The tin salt may include, but is not limited to, one or more of tin acetate, tin nitrate, tin chloride, tin bromide, tin sulfate, and tin acetylacetonate.

A molar ratio of the doping element source to the metal cation source is (0.01-15): (85-99.99). Within the above ratio range, it is advantageous to make the prepared electron functional layer 40 have better electronic functional properties, stability and the like.

The electronic functional material dispersion prepared by the method of preparing the electronic functional material dispersion includes the N-type metal oxide particle and the dopant. The metal oxide particle has good crystallinity, uniformity and stability. When the electron functional layer 40 is prepared by using the electronic functional material dispersion, the electron functional layer 40 can be doped with the dopant.

It can be understood that in some embodiments, in order to accelerate the forward aging of the optoelectronic device 100, after the optoelectronic device 100 is prepared, the optoelectronic device is further heat-treated.

In some embodiments, a temperature of the heat treatment ranges from 60° C. to 150° C., and a time of the heat treatment ranges from 1 min to 48 h.

It can be understood that when the optoelectronic device 100 further includes a functional layer conventionally used for the optoelectronic device that contributes to improving the performance of the optoelectronic device, such as an electron blocking layer, a hole blocking layer, an electron injection layer, an interface modification layer, and the like, the method of preparing the optoelectronic device 100 may further include a step of preparing the above-described functional layer by using a conventional technique in the art.

The electron functional layer prepared by the method of preparing an optoelectronic device described in the present disclosure includes the N-type metal oxide particle and the dopant, so that the optoelectronic device 100 prepared has higher luminance and longer lifetime.

Third aspect, the present disclosure further relates to a display device including the optoelectronic device 100.

The display device may be any electronic product having a display function, and the electronic product may include, but not limited to, a smartphone, a tablet computer, a laptop computer, a digital camera, a digital video camera, a smart wearable device, a smart weighing electronic scale, a vehicle-mounted display, a television or an electronic book reader. The smart wearable device may be, for example, a smart bracelet, a smart watch, a Virtual Reality (VR) helmet, and the like.

Hereinafter, the present disclosure is described in detail below by way of specific examples, the specific examples are only partial embodiments of the present disclosure and are not limited to the present disclosure.

### Example 1

The ITO conductive glass substrate was cleaned with a detergent to initially remove the stains on the surface, and then ultrasonically cleaned in deionized water, acetone, absolute ethanol and deionized water for 20 minutes to remove the impurities on the surface; and finally, blown-dried with high purity nitrogen;

The cleaned ITO conductive glass was put into a glove box, a TFB material was spin-coated by spin coating method at 3000 rpm for 30 seconds, and annealed at 150° C. for 30 minutes to obtain a hole transport layer with a thickness of 30 nm;

Blue quantum dot CdSe were spin-coated on the hole transport layer at 3000 rpm for 30 seconds, and annealed at 80° C. for 30 minutes to obtain a light-emitting layer with a thickness of 40 nm;

Zinc acetate dihydrate was added to DMF to form a zinc acetate solution with a total concentration of 0.5 mol/mL; KOH ethanol solution with a concentration of 0.5 mol/mL was dropwise added at room temperature, and continuing to stir for 1 hour to obtain a clear solution; ethyl acetate was used as a precipitant to precipitate ZnO particles, the ZnO particles were collected after centrifugation, and then dissolved and dispersed with appropriate amount of ethanol to prepare ZnO ethanol solution; the concentration of the prepared ZnO ethanol solution was diluted to 30 mg/mL, 0.3 mg of halogen element I₂ was added to 1 mL of the ZnO particle ethanol solution, and stirred for 1 hour and filtered with a 0.2 μm filter head to obtain an electronic functional material dispersion, wherein the electronic functional material dispersion includes ZnO particle, I₂ and ethanol; the above electronic functional material dispersion was spin-coated on the light-emitting layer at 3000 r/min for 30 s, and annealed at 200° C. for 30 minutes to obtain an electron transport layer with a thickness of 20 nm;

The substrate on which each functional layer is deposited was placed in an evaporation chamber and thermally evaporating Ag through a mask plate to obtain a cathode with a thickness of 100 nm;

Encapsulated in an environment with both oxygen content and water content are less than 0.1 ppm to obtain an upright quantum dot light-emitting diode.

In the electron transport layer of this example, the mass ratio of ZnO particle to I₂ was 100:1.

### Example 2

This Example is basically the same as Example 1 except that, in this Example, the amount of halogen elemental substance I₂ used in preparation of the electron transport layer was 0.1 mg.

In the electron transport layer of this example, the mass ratio of ZnO particle to I₂ was 300:1.

### Example 3

This Example is basically the same as Example 1 except that, in this Example, the amount of halogen elemental substance I₂ used in preparation of the electron transport layer was 0.5 mg.

In the electron transport layer of this example, the mass ratio of ZnO particle to I₂ was 60:1.

### Example 4

This Example is basically the same as Example 1 except that, in this Example, the amount of halogen elemental substance I₂ used in preparation of the electron transport layer was 0.05 mg.

In the electron transport layer of this example, the mass ratio of ZnO particle to I₂ was 600:1.

### Example 5

This Example is basically the same as Example 1 except that, in this Example, the amount of halogen elemental substance I₂ used in preparation of the electron transport layer was 0.6 mg.

In the electron transport layer of this example, the mass ratio of ZnO particle to I₂ was 50:1.

### Example 6

This Example is basically the same as Example 1 except that, in this Example, in the preparation of the electron transport layer, the halogen elemental substance Br₂ was used instead of the halogen elemental substance I₂.

In the electron transport layer of this example, the mass ratio of ZnO particle to Br₂ was 100:1.

### Example 7

This Example is basically the same as that of Example 1, except that in this Example, magnesium acetate was added to the zinc salt solution when the electron transport layer was prepared, and correspondingly, the electron transport layer of this Example includes Mg-doped ZnO particle (the molar doping amount of Mg was 10%) and Br₂.

### Example 8

This Example is basically the same as Example 1, except that in this Example, tin acetate was used to replace zinc acetate dihydrate in Example 1 when the electron transport layer was prepared, and correspondingly, the electron transport layer of this Example includes SnO₂ particles and I₂.

### Comparative Example 1

This Comparative Example is basically the same as Example 1, except that in this Comparative Example, the preparation method of the electron transport layer includes:

Zinc acetate dihydrate was added to DMF to form a zinc salt solution with a total concentration of 0.5 mol/mL; KOH ethanol solution with a concentration of 0.5 mol/mL was dropwise added at room temperature, and continuing to stir for 1 hour to obtain a clear solution; ethyl acetate was used as a precipitant to precipitate ZnO metal oxide particles, ZnO metal particles were collected after centrifugation, and then dissolved and dispersed with appropriate amount of ethanol to obtain ZnO ethanol solution; the concentration of the prepared ZnO ethanol solution was diluted to 30 mg/mL; the above ZnO ethanol solution was spin-coated on the light-emitting layer, at 3000 r/min for 30 s, and annealed at 200° C. for 30 min to obtain an electron transport layer with a thickness of 20 nm.

In the preparation process of the electron transport layer of the present Comparative Example, the halogen elemental substance I₂ was not used, and the prepared electron transport layer did not contain the halogen elemental substance I₂.

### Comparative Example 2

This Comparative Example is basically the same as Example 1 except that the halogen-containing compound FeCl₃ was used instead of the halogen elemental substance I₂ in Example 1 in preparation of this Comparative Example.

The electron transport layer prepared in this comparative example includes ZnO particle and FeCl₃ dopant.

### Comparative Example 3

This Comparative Example is basically the same as Example 1 except that the halogen-containing compound FeBr₃ was used instead of the halogen elemental substance I₂ in Example 1 in the preparation of this Comparative Example.

The electron transport layer prepared in this comparative example includes ZnO particle and FeBr₃ dopant.

### Comparative Example 4

This Comparative Example is basically the same as Example 1, except that in this Comparative Example, the preparation method of the electron transport layer includes:

Zinc acetate dihydrate was added to DMF to form a zinc salt solution with a total concentration of 0.5 mol/mL; 0.4 mol iodic acid was added to the zinc salt solution; KOH ethanol solution with a concentration of 0.5 mol/mL was dropwise added at room temperature, and continuing to stir for 1 hour to obtain a clear solution; ethyl acetate was used as a precipitant to precipitate ZnO particles, ZnO particles were collected after centrifugation, and then dissolved and dispersed with appropriate amount of ethanol to prepare ZnO ethanol solution; the concentration of the prepared ZnO ethanol solution was diluted to 30 mg/mL; the above ZnO ethanol solution was spin-coated onto the light-emitting layer at 3000 r/min for 30 s, and annealed at 200° C. for 30 min to obtain an electron transport layer with a thickness of 20 nm.

The electron transport layer prepared in this comparative example includes ZnO:I particle (that is I ion doped ZnO particle).

The optoelectronic devices of Examples 1 to 8 and Comparative Examples 1 to 4 were subjected to a lifetime T95 test and a brightness quenching test, respectively. The test results are shown in Table 1.

The test method of lifetime T95 is as follows: lifetime T95 was test by using a 128-channel life test system customized by Guangzhou New Vision Company, the system architecture is a constant current source driving light-emitting diode, and the constant current is 2 mA/cm². The time required when the brightness of the device is reduced to a certain proportion of the highest brightness, and the time when the brightness drops to 95% of the highest brightness is defined as T95, which is a measured lifetime.

The method of the brightness quenching test is transient fluorescence spectroscopy (TRPL) to detect the average lifetime of excitons.

It should be noted that the longer the lifetime T95 is, the higher the electron-emission stability of the optoelectronic device. The longer the average lifetime of excitons, the less likely brightness quenching is.

TABLE 1

| | average lifetime of | |
|---|---|---|
| | excitons τ_{AVG} (ns) | T95 (h) |
| Example 1 | 22.1 | 11.0 |
| Example 2 | 20.2 | 8.5 |
| Example 3 | 20.7 | 9.5 |
| Example 4 | 16.8 | 7.3 |
| Example 5 | 17.4 | 7.8 |
| Example 6 | 21.5 | 10.5 |
| Example 7 | 20.8 | 9.8 |
| Example 8 | 9.5 | 3.0 |
| Comparative Example 1 | 8.1 | 2.5 |
| Comparative Example 2 | 17.3 | 7.0 |
| Comparative Example 3 | 16.4 | 6.3 |
| Comparative Example 4 | 13.5 | 5.5 |

It can be seen from Table 1:

Compared with the optoelectronic devices of Comparative Examples 1 to 4, the optoelectronic devices of Examples 1 to 8 have a higher average lifetime of excitons and a longer lifetime T95. It can be seen that the addition of halogen elemental substance in the electron transport layer can effectively avoid quenching of the optoelectronic device and effectively improve the lifetime of the optoelectronic device. The reason may be: the halogen elemental substance has high electronegativity and a binding effect on electrons, thereby doping the dopant in the electron transport layer can slow down the charge transfer from the electron transport layer to the light-emitting layer, slowing down the charge transfer at the interface between the electron transport layer and the light-emitting layer, reducing or even avoiding the formation of positively charged defects in the N-type metal oxide particle at the interface, avoiding the brightness quenching of the optoelectronic device, and reducing the initial EL loss rate of the optoelectronic device; moreover, halogen molecule of the halogen elemental substance incorporated in the electron transport layer has high electronegativity itself, it may interact with the N-type metal oxide particle, affect the electronic structure of the N-type metal oxide particle, and cause itself to generate low energy state, which can provide suitable energy state positions for holes (positive charges), and thus can function as a hole scavenger, as a hole trapping agent, effectively neutralizes positive electric defects (holes) leaked to the electron transport layer, thereby reducing the initial EL loss rate of the optoelectronic device, improving the electroluminescence stability of the optoelectronic device, and improving the lifetime of the optoelectronic device; furthermore, the dopant neutralizes the holes leaked into the electron transport layer to prevent the holes from residing at the metal cation sites that can form high-valence metal cations, thereby reducing the formation of high-oxidation state metal cations, reducing the formation of high-oxidation state metal oxides, and reducing or even avoiding an increase in the concentration of high-oxidation state N-type metal oxides, thereby reducing the initial EL loss rate of the optoelectronic device, improving the electroluminescence stability of the optoelectronic device 100, and improving the lifetime of the optoelectronic device.

Compared with the optoelectronic devices of Examples 4 to 5, the optoelectronic devices of Examples 1 to 3 have a higher average lifetime of excitons and a longer lifetime T95It can be seen that when the mass ratio of N-type metal oxide particles to halogen elemental substance is (60-300):1, quenching of the optoelectronic devices can be more effectively avoided and the lifetime of the optoelectronic devices can be more effectively improved.

The technical solutions provided by the embodiments of the present disclosure are described in detail above. The principles and embodiments of the present disclosure have been described with reference to specific embodiments, and the description of the above embodiments is merely intended to aid in the understanding of the method of the present disclosure and its core idea. At the same time, changes may be made by those skilled in the art to both the specific implementations and the scope of disclosure in accordance with the teachings of the present disclosure. In view of the foregoing, the content of the present specification should not be construed as limiting the disclosure.

What is claimed is:

1. An optoelectronic device, comprising:
an anode, a light-emitting layer, an electron functional layer, and a cathode staked in this order;
wherein a material of the electron functional layer comprises an N-type metal oxide particle and a dopant, and an electronegativity of the dopant ranges from 2.50 to 5.00.

2. The optoelectronic device according to claim 1, wherein the electronegativity of the dopant ranges from 2.66 to 4.50.

3. The optoelectronic device according to claim 1, wherein the dopant and the N-type metal oxide particle is connected by intermolecular force.

4. The optoelectronic device according to claim 1, wherein the dopant comprises a halogen, the halogen comprises a halogen elemental substance, and the halogen elemental substance comprise one or more of Br₂ and I₂; and
the N-type metal oxide particle comprises one or more of a first doped metal oxide particle and a first undoped metal oxide particle; a material of the first undoped metal oxide particle comprises one or more of ZnO, TiO₂, and SnO₂; a metal oxide of the first doped metal oxide particle comprises one or more of ZnO, TiO₂, and SnO₂, and a doping element of the first doped metal oxide particle comprises one or more of Al, Mg, Li, Mn, Y, La, Cu, Ni, Zr, Ce, In, and Ga.

5. The optoelectronic device according to claim 4, wherein in the electron functional layer, a mass ratio of the N-type metal oxide particle to the dopant is (60-300):1;
a molar percentage content of the doping element of the first doped metal oxide particle ranges from 0.01% to 15%;
an average particle diameter of the N-type metal oxide particle ranges from 3 nm to 10 nm; and
the electron functional layer comprises one or more of an electron transport layer and an electron injection layer.

6. The optoelectronic device according to claim 1, wherein the anode and the cathode independently comprise a doped metal oxide electrode, a composite electrode, a graphene electrode, a carbon nanotube electrode, a metal elemental electrode, or an alloy electrode; a material of the doped metal oxide electrode may include, but is not limited to, one or more of indium-doped tin oxide, fluorine-doped tin oxide, antimony-doped tin oxide, aluminum-doped zinc oxide, gallium-doped zinc oxide, indium-doped zinc oxide, magnesium-doped zinc oxide, aluminum-doped magnesium oxide, and cadmium-doped zinc oxide; the composite electrode comprises AZO/Ag/AZO, AZO/Al/AZO, ITO/Ag/ITO, ITO/Al/ITO, ZnO/Ag/ZnO, ZnO/Al/ZnO, TiO₂/Ag/TiO₂, TiO₂/Al/TiO₂, ZnS/Ag/ZnS, ZnS/Al/ZnS, Ca/Al, LiF/Ca, LiF/Al, BaF₂/Al, CsF/Al, CaCO₃/Al, and BaF₂/Al; a material of the metal elemental electrode comprises one or more of Ag, Ni, Pt, Au, Ir, Cu, Mo, Al, Ca, Mg, and Ba; the alloy electrode comprises Au:Mg alloy electrode and Ag:Mg alloy electrode;
a material of the light-emitting layer comprises one or more of an organic light-emitting material and a quantum dot light-emitting material; the organic light-emitting material comprises CBP:Ir (mppy)₃ (4,4′-bis(N-carbazole)-1,1′-biphenyl:tris [2-(p-tolyl) pyridinyl iridium (III)), TCTX: Ir (mmpy) (4,4′,4″-tris(carbazol-9-yl) triphenylamine:tris [2-(p-tolyl) pyridinyl iridium), a diarylanthracene derivative, a stilbene aromatic derivative, a pyrene derivative, a fluorene derivative, a TBPe fluorescent material, a TTPX fluorescent material, a TBRb fluorescent material, a DBP fluorescent material, a delayed fluorescent material, a TTA material, a thermally activated delay material, a B—N covalent bonding-containing polymer, a hybrid local charge transfer excited state material, an exciplex luminescent material, polyacetylene and its derivatives, polyphenylene and its derivatives, polythiophene and its derivatives, and polyfluorene and its derivatives; the quantum dot light-emitting material comprises one or more of a single structure quantum dot, a core-shell structure quantum dot, and a perovskite-type semiconductor material, the core-shell structured quantum dot comprises one or more shell layers; a material of the single structure quantum dot, a material of the core of the core-shell structure quantum dot, and a material of the shell of the core-shell structure quantum dot comprise one or more of a Group II-VI compound, a Group IV-VI compound, a Group III-V compound, and a Group I-III-VI compound; the Group II-VI compound comprises one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, and HgZnSTe; the Group IV-VI compound comprises one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, and SnPbSTe; the Group III-V compound comprises one or more of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, InNSb, AIPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and InAlPSb; the Group I-III-VI compound comprises one or more of CuInS₂, CuInSe₂, and AgInS₂;
the perovskite-type semiconductor material comprises a doped or undoped inorganic perovskite-type semiconductor, or an organic-inorganic hybrid perovskite-type semiconductor, a general structural formula of the inorganic perovskite-type semiconductor is AMX₃, where A is a Cs⁺ ion, M is a divalent metal cation comprising one or more of Pb²⁺, Sn²⁺, Cu²⁺, N²⁺, Cd²⁺, Cr²⁺, Mn²⁺, Co²⁺, Fe²⁺, Ge²⁺, Yb²⁺, and Eu²⁺, and X is a halogen anion comprising one or more of Cl⁻, Br⁻, and I⁻; a general structural formula of the organic-inorganic hybrid perovskite-type semiconductor is BMX₃, where B is an organic amine cation comprising CH₃(CH₂)ₙ₋₂NH₃⁺ or [NH₃(CH₂)ₙNH₃]²⁺, where n≥2, M is a divalent metal cation comprising one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺, and Eu²⁺, and X is a halogen anion comprising one or more of Cl⁻, Br⁻, and I⁻;
the optoelectronic device further comprises a hole transport layer disposed between the anode and the light-emitting layer; a material of the hole transport layer comprises one or more of an organic hole transport material and an inorganic hole transport material; the organic hole transport material is selected from one or more of 4,4′-N,N′-dicarbazolyl-biphenyl, poly [bis(4-phenyl) (2,4,6-trimethylphenyl) amine], N, N′-diphenyl-N, N′-bis (1-naphthyl)-1,1′-biphenyl-4, 4′-diamine, N,N′-diphenyl-4,4′-diamine, N,N′-diphenyl-N,N′-bis (3-methylphenyl)-(1,1′-biphenyl)-4,4′-diamine, poly (N,N′-bis(4-butylphenyl)-N,N′-bis (phenyl) benzidine), N,N′-bis (3-methylphenyl)-N, N′-bis (phenyl)-spiro, N,N′-bis (4-(N, N′-diphenyl-amino) phenyl)-N,N′-diphenylbenzidine, 4,4′,4′-tris (N-carbazolyl)-triphenylamine, 4,4′,4′-tris (N-3-methylphenyl-N-phenylamino) triphenylamine, poly [(9,9′-dioctylfluorene-2,7-diyl)-co-(4,4′-dioctylfluorene-2,7-diyl)-co-(4,4′-(N-(4-sec-butylphenyl)-co-(4,4′-(N-(4-sec-butylphenyl) diphenylamine)], Poly (N-vinylcarbazole) and its derivatives, N,N′-bis(1-naphthyl)-N,N′-diphenyl-1,1′-biphenyl-4-4′-diamine, spiro NPB, poly (phenylenevinylene), poly [2-methoxy-5-(2-ethylhexyloxy)-1, 4-phenylenevinylene], poly [2-methoxy-5-(3′,7′-dimethyloctoxy)-1,4-phenylenevinylene], 2,2′,7,7′-tetrakis [N, N-bis (4-methoxyphenyl) amino]-9,9′-spirobifluorene, 4,4′-cyclohexylbis [N,N-bis (4-methylphenyl) aniline], 1,3-bis(carbazol-9-yl) benzene, polyaniline, polypyrrole, poly (p) phenylene vinylidene, aromatic tertiary amines, polynuclear aromatic tertiary amines, 4,4′-bis (p-carbazolyl)-1,1′-biphenyl compounds, N,N,N′,N′-tetraarylbenzidine, PEDOT: PSS and its derivatives, polymethacrylates and its derivatives, poly (9,9-octylfluorene) and its derivatives, and poly (spirofluorene) and its derivatives; the inorganic hole transport material is selected from one or more of a doped graphene, an undoped graphene, a P-type metal oxide particle, a metal sulfide, a metal selenide, and a metal nitride; the P-type metal oxide particle comprises one or more of a second doped metal oxide particle and a second undoped metal oxide particle; the metal oxide of the second doped metal oxide particle and the metal oxide of the second undoped metal oxide particle each independently comprises one or more of MoO₃, WO₃, NiO, CrO₃, CuO, Cu₂O, and V₂O₅, and a doping element in the second doped metal oxide particle comprises one or more of Mo, W, Ni, Cr, Cu, and V; the metal sulphide comprises one or more of CuS, MoS₃, and WS₃; the metal selenide comprises one or more of MoSe₃, and WSe₃; the metal nitride comprises P-type gallium nitride;
the optoelectronic device further comprises a hole injection layer disposed between the anode and the hole transport layer, and a material of the hole injection layer is selected from one or more of, 2,3,6,7,10,11-hexacyano-1,4,5,8,9,12-hexaazabenzophenanthrene, PEDOT, PEDOT:PSS, PEDOT:PSS:s-MoO₃ derivative, 4,4′,4′-tris (N-3-methylphenyl-N-phenylamino) triphenylamine, tetracyanoquinone dimethane, copper phthalocyanine, nickel oxide, molybdenum oxide, tungsten oxide, vanadium oxide, molybdenum sulfide, tungsten sulfide, and copper oxide.

7. A method of preparing an optoelectronic device, comprising:
providing an optoelectronic device preform comprising a first electrode;
providing an electronic functional material dispersion comprising an N-type metal oxide particle, a dopant and a first organic solvent, and disposing the electronic functional material dispersion on the optoelectronic device preform to obtain an electron functional layer, and an electronegativity of the dopant ranges from 2.50 to 5.00; and
forming a second electrode on the electron functional layer to obtain the optoelectronic device.

8. The method according to claim 7, wherein the first electrode is an anode, the second electrode is a cathode, and the optoelectronic device preform further comprises a light-emitting layer disposed on the first electrode.

9. The method according to claim 7, wherein the first electrode is a cathode electrode, the second electrode is an anode electrode, and the step of forming a second electrode on the electron functional layer comprises:
forming a light-emitting layer and a second electrode stacked in this order on the electron functional layer.

10. The method according to claim 7, wherein the electronegativity of the dopant ranges from 2.66 to 4.50;
the dopant comprises a halogen, the halogen comprises a halogen elemental substance, and the halogen elemental substance comprise one or more of Br₂ and I₂;
the N-type metal oxide particle comprises one or more of a first doped metal oxide particle and a first undoped metal oxide particle; a material of the first undoped metal oxide particle comprises one or more of ZnO, TiO₂, and SnO₂; a metal oxide of the first doped metal oxide particle comprises one or more of ZnO, TiO₂, and SnO₂, and a doping element of the first doped metal oxide particle comprises one or more of Al, Mg, Li, Mn, Y, La, Cu, Ni, Zr, Ce, In, and Ga;
the first organic solvent comprises one or more of an alcohol solvent and an alcohol ether solvent; the alcoholic solvent comprises one or more of ethanol, isopropyl alcohol, butanol, n-pentanol, and isoamyl alcohol; and the alcohol ether solvent comprises ethylene glycol monomethyl ether.

11. The method according to claim 7, wherein a concentration of the N-type metal oxide particle in the electron functional material dispersion ranges from 10 mg/mL to 30 mg/mL;
a concentration of the dopant in the electron functional material dispersion ranges from 0.1 mg/mL to 0.5 mg/mL.

12. The method according to claim 7, wherein after disposing the electron functional material dispersion on the optoelectronic device preform further comprises annealing, a temperature of the annealing ranges from 100° C. to 200° C., and a time of the annealing is ranges from 10 minutes to 60 minutes.

13. The method according to claim 7, wherein a method of preparing the electronic functional material dispersion comprises:
dissolving a metal cation source in a second organic solvent to obtain a metal cation source solution;
adding an alkali to the metal cation source solution to obtain a metal oxide solution;
adding a precipitant to the metal oxide solution to obtain an N-type metal oxide particle;
dispersing the N-type metal oxide particle in the first organic solvent to obtain an N-type metal oxide particle dispersion; and
adding a dopant to the N-type metal oxide particle dispersion to obtain the electronic functional material dispersion.

14. The method according to claim 13, wherein the metal cation source comprises one or more of a zinc source, a titanium source, and a tin source; the zinc source comprises one or more of zinc acetate, zinc sulfate, zinc nitrate, and zinc chloride; the titanium source comprises one or more of titanium acetate, titanium sulfate, titanium nitrate, and titanium chloride; and
the tin source comprises one or more of tin acetate, tin sulfate, tin nitrate, and tin chloride;
the second organic solvent comprises one or more of dimethyl sulfoxide, and
dimethylformamide;
the alkali comprises one or more of potassium hydroxide, sodium hydroxide, aqueous ammonia, and tetramethylammonium hydroxide;
the N-type metal oxide particle comprises one or more of zinc oxide, titanium oxide, and tin oxide; and
the precipitant comprises one or more of ethyl acetate, n-hexane, and n-heptane.

15. The method according to claim 14, wherein a concentration of the metal cation source in the metal cation source solution ranges from 0.1 mol/L to 1 mol/L;
a molar ratio of the hydroxide radical in the alkali to the metal cation in the metal cation source is (1.5-3.0):1;
a volume ratio of the precipitant to the metal oxide solution is (3-6): 1;
a doping element source is further added to the metal cation source solution, the doping element source comprises one or more of a magnesium salt, a lithium salt, a manganese salt, an yttrium salt, a lanthanum salt, a copper salt, a nickel salt, a zirconium salt, a cerium salt, an indium salt, a gallium salt, and a tin salt; and a molar ratio of the doping element source to the metal cation source is (0.01-15):(85-99.99).

16. The method according to claim 8, wherein the first electrode is the anode and the second electrode is the cathode, and the optoelectronic device preform further comprises a hole transport layer disposed between the first electrode and the light-emitting layer.

17. The method according to claim 8, wherein the first electrode is the anode and the second electrode is the cathode, and the optoelectronic device preform further comprises a hole transport layer and a hole injection layer, and the hole injection layer is disposed between the first electrode and the hole transport layer.

18. The method according to claim 9, wherein the first electrode is the cathode and the second electrode is the anode, and the step of forming a second electrode on the electron functional layer comprises:
sequentially forming a light-emitting layer, a hole transport layer, and a second electrode on the electron functional layer.

19. The method according to claim 9, wherein the first electrode is the cathode and the second electrode is the anode, the step of forming a second electrode on the electron functional layer comprises:
sequentially forming a light-emitting layer, a hole transport layer, a hole injection layer, and a second electrode on the electron functional layer.

20. A display device, comprising an optoelectronic device, the optoelectronic device comprising:
an anode, a light-emitting layer, an electron functional layer, and a cathode staked in this order;
wherein a material of the electron functional layer comprises an N-type metal oxide particle and a dopant, and an electronegativity of the dopant ranges from 2.50 to 5.00.
